(19) United States
(12) Patent Application Publication
(10) Pub. No.: US 2025/0113511 A1
(43) Pub. Date: Apr. 3, 2025

(54) METHOD OF MANUFACTURING A BIPOLAR TRANSISTOR

(71) Applicant: STMicroelectronics International N.V., Geneva (CH)

(72) Inventors: Edoardo BREZZA, Leuven (BE); Alexis GAUTHIER, Meylan (FR)

(73) Assignee: STMicroelectronics International N.V., Geneva (CH)

(21) Appl. No.: 18/903,368

(22) Filed: Oct. 1, 2024

(30) Foreign Application Priority Data
Oct. 2, 2023 (FR) 2310501

(51) Int. Cl. H01L 29/66; H01L 21/764; H01L 29/06; H01L 29/08; H01L 29/10; H01L 29/737

(52) U.S. Cl. CPC H10D 10/021; H01L 21/764; H10D 10/861; H10D 62/115; H10D 62/136; H10D 62/137; H10D 62/177

(57) ABSTRACT

To manufacture a bipolar transistor, a first stack of layers including a first layer made of the material of the base of the bipolar transistor is formed between second and third insulating layers. A first cavity is then formed crossing the first stack in such a way as to reach the substrate. The forming of the first cavity includes an etching of no layer covering the first layer other than the third layer. A first portion of the collector of the bipolar transistor and a second portion of the base of the bipolar transistor are then formed in the first cavity.

### PRIORITY CLAIM

This application claims the priority benefit of French Application for Patent No. 2310501, filed on Oct. 2, 2023, the content of which is hereby incorporated by reference in its entirety to the maximum extent allowable by law.

### TECHNICAL FIELD

The present disclosure generally concerns electronic devices and their manufacturing methods, and more precisely bipolar transistors and their manufacturing methods.

### BACKGROUND

A bipolar transistor is a semiconductor-based electronic device of the family of transistors. Its operating principle is based on two PN junctions, a forward junction and a reverse junction.

Bipolar transistor manufacturing methods may be problematical. For example, the etching of a thick stack of layers during the forming of the emitter may cause the forming of non-planar layers. Such layers may cause problems during the forming of contacts.

### SUMMARY

An embodiment provides a method of manufacturing a bipolar transistor comprising: a) forming, on a substrate, a first stack of layers comprising a first layer made of the material of the base of the bipolar transistor between second and third insulating layers; b) forming a first cavity crossing the first stack in such a way as to reach the substrate, wherein forming the first cavity comprises etching no layer covering the first layer other than the third layer; and c) forming a first portion of the collector of the bipolar transistor and a second portion of the base of the bipolar transistor in the first cavity.

According to an embodiment, the first and second portions are formed by epitaxial growth.

According to an embodiment, the first portion is closer to the bottom of the first cavity than the second portion.

According to an embodiment, the method comprises, after step c), d) forming a fourth insulating layer covering an upper surface of the third layer and an upper surface of the second portion, the fourth layer comprising an opening exposing a portion of an upper surface of the second portion.

According to an embodiment, the fourth layer is planar.

According to an embodiment, the method comprises, after step d), e) forming a second stack of layers comprising a fifth layer made of the material of the emitter of the bipolar transistor and a sixth insulating layer covering the fifth layer.

According to an embodiment, the fifth layer is in contact with the fourth layer and fills the opening in the fourth layer.

According to an embodiment, the thickness of the fifth layer is substantially equal to ten times the thickness of the fourth layer.

According to an embodiment, the method comprises the partial etching of the fourth, fifth, and sixth layers.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 shows a device resulting from a step of a bipolar transistor manufacturing method;

FIG. 2 shows a device resulting from another step of the bipolar transistor manufacturing method;

FIG. 3 shows a device resulting from another step of the bipolar transistor manufacturing method;

FIG. 4 shows a device resulting from another step of the bipolar transistor manufacturing method;

FIG. 5 shows a device resulting from another step of the bipolar transistor manufacturing method;

FIG. 6 shows a device resulting from another step of the bipolar transistor manufacturing method;

FIG. 7 shows a device resulting from another step of the bipolar transistor manufacturing method;

FIG. 8 shows a device resulting from another step of the bipolar transistor manufacturing method;

FIG. 9 shows a device resulting from another step of the bipolar transistor manufacturing method; and

FIG. 10 shows a device resulting from another step of the bipolar transistor manufacturing method.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

Unless specified otherwise, the expressions “conductive” and “insulating” signify “electrically conductive” and “electrically insulating”.

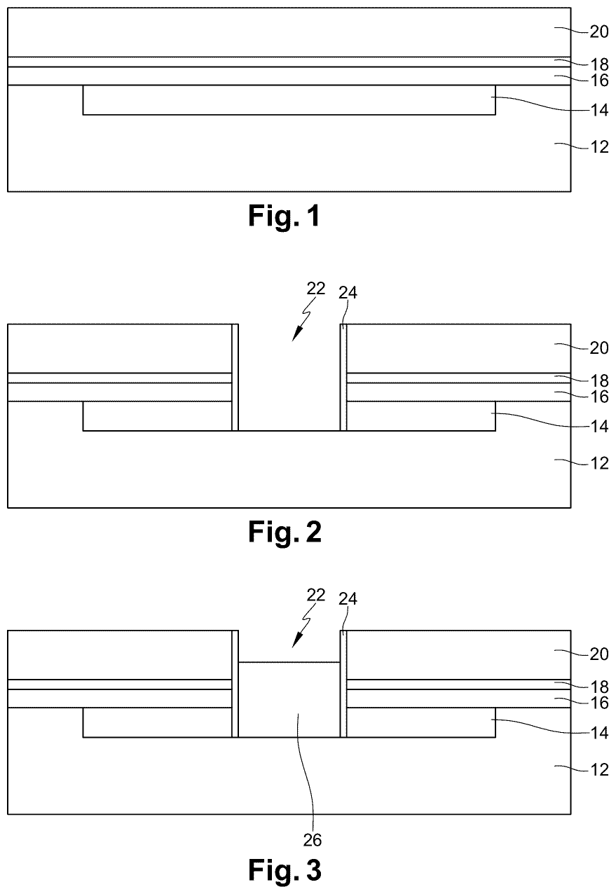

FIGS. 1 to 10 show steps, preferably successive, of a method of manufacturing a bipolar transistor 10.

FIG. 1 shows a device resulting from a step of a method of manufacturing a bipolar transistor 10.

During this step, a substrate 12 is formed. Substrate 12 forms the substrate inside and on top of which transistor 10 will be formed. Substrate 12 is, for example, made of a semiconductor material, for example made of silicon, for example of silicon doped with N-type dopants. A portion of the substrate corresponds, for example, to a portion of the collector of bipolar transistor 10.

The step of FIG. 1 comprises, for example, forming an insulating trench 14. Trench 14 is, for example, a simple shallow insulating trench (SSTI). Trench 14 corresponds to an insulating region located in substrate 12, preferably at the surface of substrate 12. Thus, an upper surface of trench 14 is coplanar with an upper surface of substrate 12. Region 14 is preferably made of an oxide, for example of silicon oxide.

The step of FIG. 1 further comprises forming an insulating layer 16 on the structure. More precisely, layer 16 covers the upper surface of substrate 12 and of trench 14. Layer 16 preferably entirely covers trench 14. Layer 16 is preferably in contact with trench 14 and with substrate 12. Layer 16 is preferably made of the same material as region 14. The sum of the thicknesses of layer 14 and of trench 14 is preferably less than 70 nm, for example substantially equal to 50 nm.

The step of FIG. 1 further comprises forming a layer 18. Layer 18 is made of the material of the base of transistor 10. Layer 18 is, for example, made of a semiconductor material. Layer 18 is, for example, made of polysilicon, for example P-type doped. Layer 18 covers at least trench 14. Layer 18 is preferably in contact with layer 16. Layer 18 preferably extends over the entire layer 16.

The step of FIG. 1 also comprises forming a layer 20. Layer 20 is made of a single material, preferably a homogeneous material. Layer 20 is preferably a single layer and is preferably not formed of other layers. Layer 20 is an insulating layer. Layer 20 is, for example, made of silicon nitride. Advantages of using a single layer of homogenous material for layer 20 include: simplified integration; reduction of cost; reduced variability in stack thickness because a single deposit can be used; improved uniformity when etching between different geometries (compared to a stack of layers which requires different etch chemistries with different etching speeds dependent on component geometry); and no need for interface between different materials.

Layer 20 covers at least trench 14. Preferably, layer 20 extends over the entire layer 18. Layer 20 rests on, and is in contact with, layer 18. Preferably, layer 20 is not separated, even partially, from layer 18 by another layer or layer portion.

The sum of the thicknesses of trench 14 and of layers 16, 18, and 20 is preferably less than 230 nm, preferably less than 200 nm, preferably less than or substantially equal to 150 nm.

FIG. 2 shows a device resulting from another step of the method of manufacturing a bipolar transistor 10.

The step of FIG. 2 comprises a step of etching of the structure to reach substrate 12 at the level of trench 14. In other words, the step of FIG. 2 comprises forming a cavity 22. Cavity 22 crosses a stack comprising layers 16, 18, 20 and trench 14. The cavity thus reaches substrate 12. The bottom of cavity 22 is thus formed of a portion of substrate 12. The bottom of cavity 22 is preferably substantially coplanar with the lower surface of trench 14.

Said stack preferably comprises no other layer than layers 16, 18, 20 and trench 14. Said stack comprises a single layer, that is, layer 20, above layer 18. In other words, during the step of etching of the stack, layer 18 is only covered, for example at least in front of trench 14, for example at least in front of the location of the bipolar transistor, with insulating layer 20. The etch step of step 2 comprises the etching of no layer covering layer 18 other than layer 20.

The height of cavity 22 is preferably less than 230 nm, preferably less than 200 nm, preferably less than or substantially equal to 150 nm.

The step of FIG. 2 may, optionally, comprise the forming of spacers 24. Spacers 24 are located on the lateral walls of cavity 22. The spacers cover the lateral walls of the layers in cavity 22. Thus, the lateral walls of layers 16, 18, 20 and of trench 14 forming the walls of cavity 22 are covered, for example fully covered, with spacers 24.

FIG. 3 shows a device resulting from another step of the bipolar transistor manufacturing method.

The step of FIG. 3 comprises a step of epitaxial growth of substrate 12 in cavity 22. The step of FIG. 3 thus comprises the forming of an epitaxial region 26 in cavity 22.

Region 26 preferably extends from the bottom of cavity 22 to a level higher than the upper surface of layer 18, and preferably lower than the upper surface of layer 20. The lateral walls of layer 18 located at the same level as the lateral walls of cavity 22 are thus entirely separated by region 26 and spacers 24.

Region 26 is in contact with substrate 12 and with spacers 24. Region 26 is thus separated from layers 16, 18, 20 and from trench 14 by spacers 24.

Region 26 is made of a semiconductor material, for example of silicon, for example of N-type doped silicon. Region 26 is preferably made of the material of substrate 12. Region 26 preferably corresponds to a portion of the collector of bipolar transistor 10.

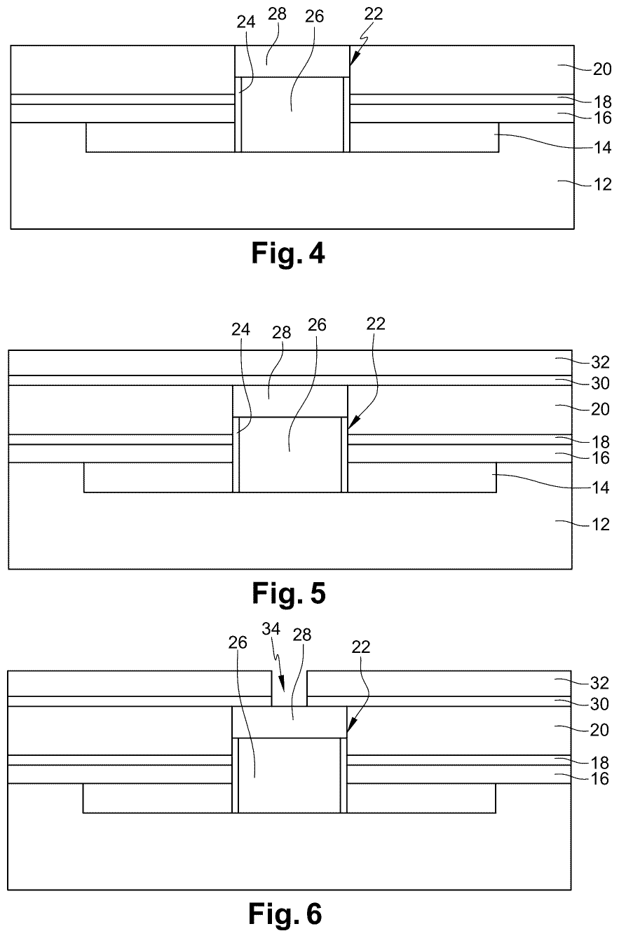

FIG. 4 shows a device resulting from another step of the bipolar transistor manufacturing method.

The step of FIG. 4 comprises the parallel etching (i.e., partial removal) of spacers 24. More precisely, the portions of the spacers located above the upper surface of region 26 are etched. Thus, the upper surfaces of spacers 24 are preferably, after the etching, substantially coplanar with the upper surface of region 26.

The step of FIG. 4 further comprises forming a region 28. Region 28 is, for example, formed by epitaxial growth, for example from region 26. Epitaxial region 28 preferably fills cavity 22. Region 28 preferably extends from the upper surfaces of spacers 24 and of region 26. Region 28 extends between the lateral surfaces of layer 20 located in cavity 22. Thus, region 28 is laterally in contact with layer 20, preferably only with layer 20. Preferably, region 28 is preferably not in contact with layer 18. Region 28 is in contact with region 26 and spacers 24.

The upper surface of the structure, corresponding to the upper surface of region 28 and the upper surface of layer 20, is preferably planar.

Region 28 is made of a semiconductor material, for example of silicon, for example of P-type doped silicon. Region 28 corresponds to a portion of the base region of transistor 10.

FIG. 5 shows a device resulting from another step of the bipolar transistor manufacturing method.

During this step, a layer 30 is formed on the structure. More precisely, layer 30 preferably covers the upper surface of layer 20 and the upper surface of region 28. Layer 30 entirely covers, for example, layer 20 and region 28. Layer 30 is preferably in contact with region 28 and layer 20, preferably with the entire upper surface of region 28 and of layer 20. Layer 30 is, for example, made of the same material as layer 16. Layer 30 is, for example, made of silicon oxide. Layer 30 has, for example, a thickness in the range from 4 nm to 20 nm.

The step of FIG. 5 further comprises forming a layer 32. Layer 32 preferably covers layer 30, preferably fully covers layer 30. Layer 32 is preferably in contact with layer 30, preferably in contact with the entire layer 30. Layer 32 is preferably made of the same material as layer 20, for example of silicon nitride. Layers 30 and 32 are preferably made of different materials. The material of layer 32 is preferably a material selectively etchable over the material of layer 30. By selectively etchable, there is meant that the material of layer 32 can be etched, by an etching method, at least twice faster than the material of layer 30, for example at least ten times faster. The thickness of layer 32 is, for example, in the range from 8 nm to 40 nm.

FIG. 6 shows a device resulting from another step of the bipolar transistor manufacturing method.

During this step, a cavity 34 is formed in layers 30 and 32, preferably only in layers 30 and 32. Cavity 34 is located in front of cavity 22. In other words, cavity 34 is located in front of regions 26 and 28. Cavity 34 extends along the entire height of layers 30 and 32. Cavity 34 thus reaches region 28. The bottom of cavity 34 is formed of the upper surface of region 28, preferably only of the upper surface of region 28. The lateral walls of cavity 34 are formed by lateral walls of layers 30 and 32. Layer 32 is, for example, physically etched by a succession of a photolithography and then of a dry etch method. Layer 32 is then used as a mask for a step of (isotropic) wet etching of layer 30.

The dimensions of cavity 34, in particular the horizontal dimensions, that is, for example in a plane parallel to the plane of the upper surface of layer 20, are smaller than the dimensions of cavity 22 for example, in particular than the horizontal dimensions of cavity 22. Thus, a portion of the upper surface of region 28 is not exposed by the etching forming cavity 34. In other words, a portion of layers 30, 32, preferably a portion located in front of region 28 and surrounding cavity 34, is not etched during the step of FIG. 6.

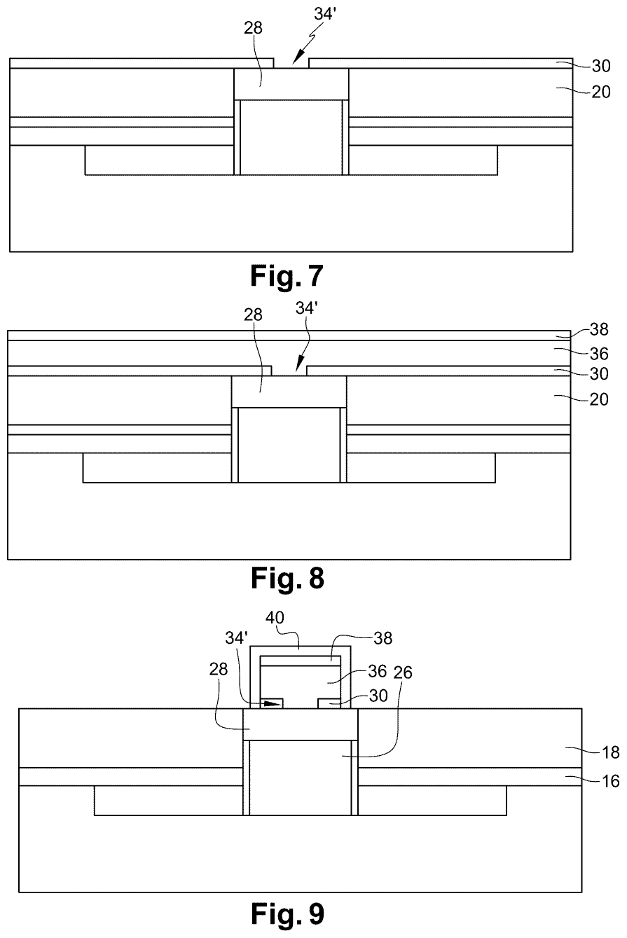

FIG. 7 shows a device resulting from another step of the bipolar transistor manufacturing method.

During this step, layer 32 is removed. Layer 30 is thus exposed at least at the location of the transistor. Preferably, layer 32 is fully removed. Layer 30 is thus preferably fully exposed.

Cavity 34 is thus replaced with a cavity, or opening, 34′ corresponding to the portion of cavity 34 defined by layer 30 and region 28.

FIG. 8 shows a device resulting from another step of the bipolar transistor manufacturing method.

During this step, a layer 36 is formed on the structure. More precisely, layer 36 preferably covers the upper surface of layer 30 and the bottom and the walls of cavity 34′. Layer 36 thus preferably covers the upper surface of layer 30, the lateral walls of layer 30 forming the lateral walls of cavity 34′ and the portion of the upper surface of region 28 forming the bottom of cavity 34′. Layer 36 fully covers, for example, layer 30 and the walls and the bottom of cavity 34′. Layer 36 is preferably in contact with region 28 in cavity 34′ and layer 30. Layer 36 is made of the material of the emitter region of bipolar transistor 10. Layer 36 is, for example, made of polysilicon, for example of N-type doped polysilicon. Layer 36 has, for example, a thickness in the range from 50 nm to 100 nm. Layer 30 is, for example, substantially ten times smaller than layer 36.

The step of FIG. 8 further comprises the forming of a layer 38. Layer 38 preferably covers layer 36, preferably fully covers layer 36. Layer 38 is preferably in contact with layer 36, preferably in contact with the entire layer 36. Layer 38 is preferably made of the same material as layer 30, for example of silicon oxide.

Layer 30 having a smaller thickness as compared with the thickness of layer 36, the upper surface of layer 36 is substantially planar and comprises no dip.

One could have chosen, as in usual methods, to form, at the step of FIG. 1, a stack of a larger number of insulating layers, to form L-shaped insulating elements on the upper surface of region 28 to delimit cavity 34′. Layers 36 and 38 would then not be planar and would form a dip in line with cavity 34′. Such a dip would cause problems of contact with the emitter of the bipolar transistor.

FIG. 9 shows a device resulting from another step of the bipolar transistor manufacturing method.

During this step, layers 30, 36, 38 are partially etched. In other words, layers 30, 36, 38 are fully etched except for portions of each of layers 30, 36, 38 located in front of region 28. Layers 38 and 36 are for example etched by a succession of a photolithography and of an (anisotropic) dry etching. Layer 30 is used as a stop layer for this etching. Then, layer 30 is etched by wet chemistry (isotropic).

Thus, after the partial etching of layers 30, 36, 38, a portion of each layer 30, 36, 38 is kept in front of region 28. Said portion of layer 30 surrounds and delimits cavity 34′. The portion of layer 36 fills cavity 34′ and preferably fully covers the portion of layer 30. The portion of layer 38 preferably fully covers layer 36. The portions of layers 30, 36, 38 preferably have coplanar lateral walls. Preferably, a portion of the upper surface of region 28, for example a portion surrounding the portion covered by the portion of layer 30, is not covered by the portions of layers 30, 36, 38.

The step of FIG. 9 further comprises forming a layer 40 made of an insulating material, for example the same material as layer 16, for example of silicon oxide. Layer 40 covers the lateral walls of the portions of layers 30, 36, 38 and the upper surface of the portion de layer 38. Layer 40 cover, for example, a portion of the upper surface of region 28 surrounding the portions of layers 30, 36, 38. Layer 40 does not cover layer 20.

The step of FIG. 9 then comprises removing, for example by etching, layer 20. Layer 20 is preferably fully removed. At least a portion of layer 20 surrounding region 28 is removed. At least a portion of the layer 18 surrounding region 26 is thus exposed.

The step of FIG. 9 then comprises the epitaxial growth of layer 18. The growth of epitaxial layer 18 is maintained until layer 18 is in lateral contact with region 28. Thus, the upper surface of layer 18 is higher than the lower surface of region 28. Preferably, the upper surface of layer 18 is lower than the upper surface of region 28. For example, the upper surface of layer 18 and the upper surface of region 28 are coplanar.

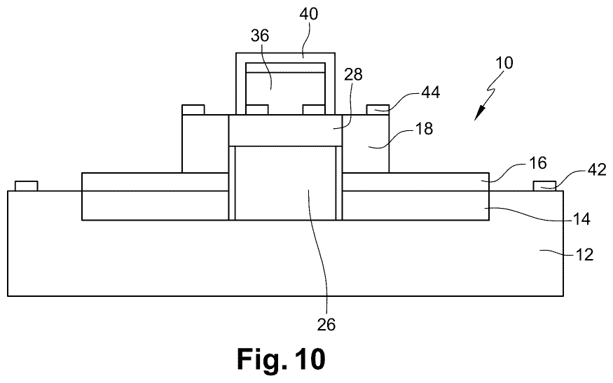

FIG. 10 shows a device resulting from another step of the bipolar transistor manufacturing method.

During this step, layers 16 and 18 are partially etched. More precisely, layers 16 and 18 are partially etched to expose the upper surface of substrate 12. Layer 16 is, for example, etched so that a portion of layer 16 at least partially covers trench 14. Thus, the portions of layer 16 covering substrate 12 around trench 14 are removed. Further, layer 18 is partially etched so that a portion of layer 18 surrounding region 28 is kept. Thus, said portion of layer 18 surrounds region 28 and is in lateral contact with region 28.

The step of FIG. 10 further comprises the forming of contact pads. In particular, the step of FIG. 10 comprises: forming contact pads 42, resting on substrate 12 and corresponding to collector contact pads; forming contact pads 44, resting on layer 18 and corresponding to base contact pads; and forming of contact pads, not shown, resting on layer 36 and corresponding to emitter contact pads.

An advantage of the described embodiments is that the etching of cavity 22 implies the etching of a thinner stack, which is thus easier to etch. It is thus possible to form a smaller cavity, for example having critical dimensions less than 200 nm.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. A bipolar transistor manufacturing method, comprising:
a) forming, on a substrate, a first stack of layers comprising a first layer made of the material of the base of the bipolar transistor between a second insulating layer and a third insulating layer, wherein the third insulating layer is a single layer;
b) forming a first cavity crossing the first stack in such a way as to reach the substrate, wherein forming the first cavity comprises etching of no layer covering the first layer other than the third insulating layer; and
c) forming a first portion of the collector of the bipolar transistor and a second portion of the base of the bipolar transistor in the first cavity.

2. The method according to claim 1, wherein the first and second portions are formed by epitaxial growth.

3. The method according to claim 1, wherein the first portion is closer to the bottom of the first cavity than the second portion.

4. The method according to claim 1, further comprising, after c), d) forming a fourth insulating layer covering an upper surface of the third layer and an upper surface of the second portion, and forming an opening in the fourth layer exposing a portion of an upper surface of the second portion.

5. The method according to claim 4, wherein the fourth layer is planar.

6. The method according to claim 4, further comprising, after d), e) forming a second stack of layers comprising a fifth layer made of the material of the emitter of the bipolar transistor and a sixth insulating layer covering the fifth layer.

7. The method according to claim 6, wherein the fifth layer is in contact with the fourth layer and fills the opening in the fourth layer.

8. The method according to claim 6, wherein the thickness of the fifth layer is substantially equal to ten times the thickness of the fourth layer.

9. The method according to claim 6, further comprising partially etching the fourth, fifth, and sixth layers.

10. A bipolar transistor manufacturing method, comprising:
forming a first layer made of an insulating material on a substrate;
forming a second layer made of a polysilicon material on the first layer;
forming a third layer made of an insulating material on the second layer;
wherein the third layer is a single layer;
forming a first cavity crossing the first, second and third layers to reach the substrate by etching of no layer covering the second layer other than the third layer;
epitaxially growing a collector region of the bipolar transistor from an exposed portion of the substrate;
epitaxially growing a first portion of a base region of the bipolar transistor from the collector region, said first portion of the base region in contact with the second layer which provides a second portion of the base region of the bipolar transistor;
forming a fourth layer made of an insulating material on the third layer and the first portion of the base region;
forming an opening crossing the fourth layer;
forming an emitter region of the bipolar transistor in the opening.

11. The method according to claim 10, further comprising:
forming a trench insulating region at an upper surface of the substrate; and
wherein forming the first cavity comprises extending the first cavity through the trench insulating region.

12. The method according to claim 10, wherein the third layer is made solely of silicon nitride.

13. The method according to claim 10, wherein forming the first cavity is performed before covering the third layer with any other material layer.
